(19) United States
(12) Patent Application Publication
(10) Pub. No.: US 2024/0413142 A1
(43) Pub. Date: Dec. 12, 2024

(54) LIGHT-EMITTING ELEMENT-THIN FILM TRANSISTOR INTEGRATION STRUCTURE

(71) Applicant: Korea University Research and Business Foundation, Seoul (KR)

(72) Inventor: In Hwan LEE, Seoul (KR)

(73) Assignee: Korea University Research and Business Foundation, Seoul (KR)

(21) Appl. No.: 18/700,926

(22) PCT Filed: Oct. 13, 2022
(86) PCT No.: PCT/KR2022/015504

§ 371 Date: Apr. 12, 2024

(30) Foreign Application Priority Data
Oct. 19, 2021 (KR) 10-2021-0138964
Oct. 11, 2022 (KR) 10-2022-0129462

(51) Int. Cl. H01L 25/16; H01L 27/12; H01L 33/12; H01L 33/46; H01L 33/62

(52) U.S. Cl. CPC H01L 25/167; H01L 27/1225; H01L 33/12; H01L 33/46; H01L 33/62; H01L 2933/0025; H01L 2933/0066

(57) ABSTRACT

Disclosed is a Light-Emitting Device-Thin Film Transistor (LED-TFT) integration structure, comprising a substrate comprising a light emitting area and a driving area; a metal reflective film formed on the substrate; a buffer layer formed on the metal reflective film; LED disposed in the light emitting area; a protective layer formed on the LED; a thin film transistor disposed in the driving area and configured to drive the LED; and an ohmic contact metal for electrically connecting a cathode of the LED with the metal reflective film, wherein the LED and the thin film transistor are integrally formed on the substrate.

### TECHNICAL FIELD

The present invention relates to a Light-Emitting Device-Thin Film Transistor (LED-TFT) integration structure and a method of fabricating the LED-TFT integration structure, and more particularly to an LED-TFT integration structure whose fabrication process does not include a transfer process and whose lower part includes a metal reflective film, and a method of fabricating the LED-TFT integration structure.

### BACKGROUND ART

As representative examples of a technology for forming a light-emitting device semiconductor thin film of an existing Light-Emitting Device-Thin Film Transistor (LED-TFT) integration structure, there are Metal Organic CVD (MOCVD) method, Molecular Beam Epitaxy (MBE) method, and the like. When a semiconductor thin film is produced by these methods, a substrate temperature must be maintained at about 1,000 to 1,100° C.

Accordingly, a material for a substrate on which a light-emitting device semiconductor thin film of an LED-TFT integration structure is formed has been limited to single crystal sapphire (Al₂O₃), silicon (Si), silicon carbide (SiC), and the like which have relatively high deformation temperature.

However, in the case of sapphire substrates, it is difficult to produce large-area wafers of 6 inches or more, and the production cost is high, making it difficult to implement large-area displays such as large TVs.

In addition, in the case of sapphire substrates, deterioration problems such as distortion of the substrate itself may occur due to thermal expansion of the substrate, and damage to the thin film may occur due to a lattice constant difference and thermal expansion coefficient difference between a semiconductor thin film formed on the substrate and the substrate.

In particular, for example, a process of transferring an LED to a second substrate such as a glass substrate during a micro-LED display manufacturing process is essential when growing a semiconductor thin film on a single crystal sapphire substrate using the MOCVD method.

When LED transfer is required, the cost of LED production and transfer processes is high, so the production cost of a display increases significantly, and as a result, the production cost of large TVs using LEDs such as micro-LED increases.

In addition, in an existing LED-TFT integration structure, light generated from the LED travels in all directions, so there was a problem in that the light was absorbed again inside the LED and converted into heat energy. In other words, in the existing LED-TFT integration structure, only a portion of light generated from the LED exits a device, resulting in low light extraction efficiency.

To address such a problem, the technology (Korean Patent Application Publication No. 10-2007-0094344) to improve light extraction efficiency using a DBR mirror was disclosed, but in this technology using a DBR mirror, the manufacturing process is complicated because a process of laminating the DBR mirror is added, and there is a problem of increasing manufacturing costs.

Therefore, there is a need for a technology that can grow a semiconductor thin film directly on a substrate without a transfer process and manufacture an LED-TFT integration structure capable of increasing light extraction efficiency by including a metal reflective film at the bottom.

### DISCLOSURE

### Technical Problem

Therefore, the present invention has been made in view of the above problems, and it is one object of the present invention to provide a Light-Emitting Device-Thin Film Transistor (LED-TFT) integration structure fabricated directly on a substrate without a transfer process.

It is another object of the present invention to provide an LED-TFT integration structure fabricated in batches on a substrate by using an LED-TFT integration substrate and a TFT-LED integration substrate.

It is still another object of the present invention to provide an LED-TFT integration structure including a substrate and a metal reflective film, wherein the metal reflective film is included on the substrate, and the LED-TFT integration structure can extract light, generated from a light emitting layer of LED, upward using the metal reflective film to increase the amount of light emitted the top of the LED and light extraction efficiency.

It is yet another object of the present invention to provide an LED-TFT integration structure capable of lowering the growth temperature of a semiconductor thin film, compared to an existing process, by adding additional energy to a thin film growth process using a physical vapor deposition method during a fabrication process thereof.

It will be understood that technical problems of the present invention are not limited to the aforementioned problem and may be expanded in various ways without departing from the spirit and scope of the present invention.

### Technical Solution

In accordance with an aspect of the present invention, the above and other objects can be accomplished by the provision of a Light-Emitting Device-Thin Film Transistor (LED-TFT) integration structure, including: a substrate including a light emitting area and a driving area; a metal reflective film formed on the substrate; a buffer layer formed on the metal reflective film; LED disposed in the light emitting area; a protective layer formed on the LED; a thin film transistor disposed in the driving area and configured to drive the LED; and an ohmic contact metal for electrically connecting a cathode of the LED with the metal reflective film. The LED and the thin film transistor are integrally formed on the substrate.

In an embodiment, an active layer of the thin film transistor may be disposed lower than a light emitting layer of the LED.

In an embodiment, a source thin film of the thin film transistor may block light emitted from the LED from flowing into the active layer of the thin film transistor.

In an embodiment, the active layer of the thin film transistor may be an oxide semiconductor including at least one of amorphous silicon, nanocrystalline silicon, microcrystalline silicon, polycrystalline silicon, and InGaZnO-based materials.

In an embodiment, the LED-TFT integration structure may be fabricated by a process including: forming a metal reflective film on a substrate; forming a buffer layer on the metal reflective film; forming an LED in a light emitting area on the substrate; forming a protective layer on the LED; forming a thin film transistor in a driving area on the substrate; and electrically connecting a cathode of the LED with the metal reflective film using an ohmic contact metal.

In an embodiment, the LED and the thin film transistor may be fabricated in batches using an LED-TFT integration substrate. In the LED-TFT integration substrate, the substrate, the metal reflective film, the buffer layer, an LED layer, the protective layer, and a thin film transistor layer may be sequentially laminated.

In an embodiment, the LED-TFT integration structure may be fabricated by a process including: fabricating an LED-TFT integration substrate; etching the thin film transistor layer to expose the LED layer; forming a light-blocking film; forming a gate of the thin film transistor; forming TCO on the LED layer; forming an insulating protective film between the TCO and the thin film transistor; forming a source thin film and drain thin film of the thin film transistor; and electrically connecting a cathode of the LED with the metal reflective film using an ohmic contact metal.

In an embodiment, the LED and the thin film transistor may be fabricated in batches using an LED-TFT integration substrate. In the LED-TFT integration substrate, the substrate, the metal reflective film, the buffer layer, an LED layer, TCO, the protective layer, and a thin film transistor layer may be sequentially laminated.

In an embodiment, the metal reflective film may include at least one of Ag and Al, and reflect light generated from the LED to increase light extraction efficiency of the LED.

In an embodiment, a semiconductor thin film of the LED may be grown at low temperature by supplying additional energy to a physical vapor deposition method and a chemical vapor deposition method. The substrate may be at least one of a glass substrate, a stainless steel substrate, and a polymer substrate.

In an embodiment, the physical vapor deposition method may use at least one of a sputtering method, an e-beam deposition method and a thermal evaporation method.

In an embodiment, the additional energy may include at least one of ion beam, electron beam, plasma, ultraviolet ray, laser and LED light.

In accordance with another aspect of the present invention, there is provided an LED-TFT integration structure, including: a substrate including a light emitting area and a driving area; a protective layer formed on the substrate; a thin film transistor disposed in the driving area and configured to drive the LED; a metal reflective film formed on the thin film transistor; an LED disposed in the light emitting area; and TCO formed on the LED, wherein the thin film transistor and the LED are integrally formed on the substrate.

In an embodiment, the LED and the thin film transistor may be fabricated in batches using a TFT-LED integration substrate. In the TFT-LED integration substrate, the substrate, the protective layer, a thin film transistor layer, the metal reflective film, an LED layer, and the TCO may be sequentially laminated.

In an embodiment, the LED-TFT integration structure may be fabricated by a process including: fabricating the TFT-LED integration substrate; etching the LED layer to expose the thin film transistor layer; etching the metal reflective film; forming an insulating protective film on the TCO and the LED; exposing an upper part of the TCO; etching GI; depositing a metal thin film; and forming a gate, source thin film, and drain thin film of the thin film transistor.

### Advantageous Effects

The LED-TFT integration structure according to embodiments of the present invention may be manufactured directly on a substrate without a transfer process.

In addition, since the LED-TFT integration structure includes the LED-TFT integration substrate and the TFT-LED integration substrate, it can be manufactured in batches on a substrate.

In addition, since the LED-TFT integration structure includes a metal reflective film formed on the substrate thereof and extracts light, generated from the light emitting layer of the LED, upward using the metal reflective film, it may increase the amount of light emitted from the top of LED and the light extraction efficiency.

In addition, since additional energy is provided in the thin film growth process using the physical vapor deposition method of the fabrication process of the LED-TFT integration structure, the growth temperature of the semiconductor thin film may be lowered compared to existing processes. Accordingly, a glass substrate, stainless steel substrate, and polymer substrate having a deformation temperature of 650° C. or less may be applied to the LED-TFT integration structure.

However, the effects of the present invention are not limited to the effects described above, and can be expanded in various ways without departing from the idea and scope of the present invention.

### DESCRIPTION OF DRAWINGS

FIG. 1 is a sectional view illustrating a Light-Emitting Device-Thin Film Transistor (LED-TFT) integration structure according to an embodiment of the present invention.

FIG. 2 is a flowchart illustrating a method of fabricating the LED-TFT integration structure of FIG. 1.

FIG. 3 illustrates a substrate, metal reflective film, and buffer layer formed according to the fabrication method of FIG. 2.

FIG. 4 illustrates an LED formed according to the fabrication method of FIG. 2.

FIG. 5 is a flowchart illustrating an embodiment of a method of forming the LED of FIG. 4.

FIG. 6 illustrates a protective layer formed according to the fabrication method of FIG. 2.

FIG. 7 illustrates a thin film transistor formed according to the fabrication method of FIG. 2.

FIG. 8 illustrates electrically connecting a cathode of an LED with a metal reflective film according to the fabrication method of FIG. 2.

FIG. 9 illustrates a gate line and data line connected to the thin film transistor.

FIG. 10 is a sectional view illustrating a Light-Emitting Device-Thin Film Transistor (LED-TFT) integration structure according to another embodiment of the present invention.

FIG. 11 is a flowchart illustrating a method of fabricating the LED-TFT integration structure of FIG. 10.

FIG. 12 illustrates an LED-TFT integration substrate manufactured according to the fabrication method of FIG. 11.

FIG. 13 illustrates a thin film transistor layer etched according to the fabrication method of FIG. 11.

FIG. 14 illustrates a light-blocking film formed according to the fabrication method of FIG. 11.

FIG. 15 illustrates a gate of the thin film transistor formed according to the fabrication method of FIG. 11.

FIG. 16 illustrates TCO formed on the LED layer according to the fabrication method of FIG. 11.

FIG. 17 illustrates an insulating protective film DP formed between the TCO and the thin film transistor according to the fabrication method of FIG. 11.

FIG. 18 illustrates a source thin film and drain thin film of the thin film transistor formed according to the fabrication method of FIG. 11.

FIG. 19 illustrates electrically connecting the cathode of the LED to the metal reflective film according to the fabrication method of FIG. 11.

FIG. 20 illustrates another embodiment of an LED-TFT integration substrate.

FIG. 21 illustrates an LED-TFT integration structure fabricated using the LED-TFT integration substrate of FIG. 20.

FIG. 22 illustrates a physical vapor deposition method to form a semiconductor thin film of the LED.

FIG. 23 illustrates the types of additional energy to form the semiconductor thin film of the LED.

FIG. 24 illustrates a sectional view of an LED-TFT integration structure according to another embodiment of the present invention.

FIG. 25 is a flowchart illustrating a method of fabricating the LED-TFT integration structure of FIG. 24.

FIG. 26 illustrates a TFT-LED integration substrate manufactured according to the fabrication method of FIG. 25.

FIG. 27 illustrates a process of fabricating the TFT-LED integration structure using the LED-TFT integration substrate of FIG. 26.

### BEST MODE

Specific structural and functional descriptions of embodiments according to the concept of the present invention disclosed herein are merely illustrative for the purpose of explaining the embodiments according to the concept of the present invention. Furthermore, the embodiments according to the concept of the present invention can be implemented in various forms and the present invention is not limited to the embodiments described herein.

The embodiments according to the concept of the present invention may be implemented in various forms as various modifications may be made. The embodiments will be described in detail herein with reference to the drawings. However, it should be understood that the present invention is not limited to the embodiments according to the concept of the present invention, but includes changes, equivalents, or alternatives falling within the spirit and scope of the present invention.

The terms such as “first” and “second” are used herein merely to describe a variety of constituent elements, but the constituent elements are not limited by the terms. The terms are used only for the purpose of distinguishing one constituent element from another constituent element. For example, a first element may be termed a second element and a second element may be termed a first element without departing from the scope of rights according to the concept of the present invention.

It will be understood that when an element is referred to as being “on”, “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Other words used to describe the relationship between elements should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” in the specification should be construed as denoting that a certain characteristic, number, step, operation, constituent element, component or a combination thereof exists and not as excluding the existence of or a possibility of an addition of one or more other characteristics, numbers, steps, operations, constituent elements, components or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

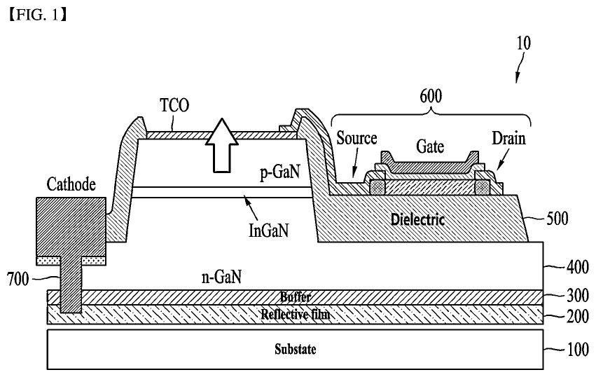

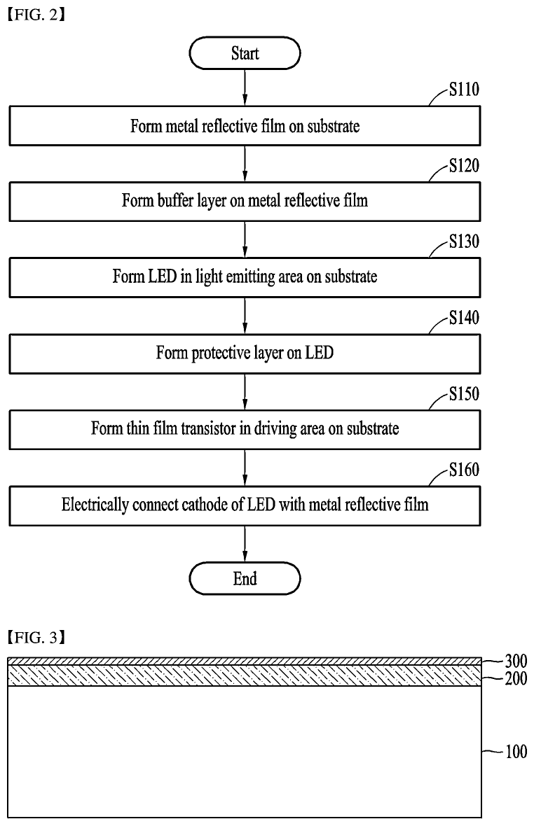

FIG. 1 is a sectional view illustrating a Light-Emitting Device-Thin Film Transistor (LED-TFT) integration structure 10 according to an embodiment of the present invention, and FIG. 2 is a flowchart illustrating a method of fabricating the LED-TFT integration structure 10 of FIG. 1.

Referring to FIG. 1, the LED-TFT integration structure 10 of the present invention may include a substrate 100, a metal reflective film 200, a buffer layer 300, an LED 400, a protective layer 500, a thin film transistor 600, and an ohmic contact metal 700.

Specifically, the LED-TFT integration structure 10 may include a substrate 100 including a light emitting area and a driving area; a metal reflective film 200 formed on the substrate 100; a buffer layer 300 formed on the metal reflective film 200; an LED 400 disposed on the light emitting area; a protective layer 500 formed on the LED 400; a thin film transistor 600 disposed on the driving area and configured to drive the LED 400; and an ohmic contact metal 700 configured to electrically connect a cathode of the LED 400 to the metal reflective film 200.

For example, the LED 400 and the thin film transistor 600 may be integrally formed on the substrate 100.

Referring to FIG. 2, LED-TFT integration structures 10 according to embodiments of the present invention may be fabricated through a step (S110) of forming the metal reflective film 200 on the substrate 100; a step (S120) of forming the buffer layer 300 on the metal reflective film 200; a step (S130) of forming the LED 400 in a light emitting area on the substrate 100; a step (S140) of forming the protective layer 500 on the LED 400; a step (S150) of forming the thin film transistor 600 in a driving area of the substrate 100; and a step (S160) of electrically connecting a cathode of the LED 400 to the metal reflective film 200 using the ohmic contact metal 700.

The LED-TFT integration structure 10 of the present invention may be directly manufactured on the substrate 100 without a transfer process.

In addition, in the LED-TFT integration structure 10, the active layer 610 of the thin film transistor 600 is disposed lower than a light emitting layer 420 of the LED 400, so leakage current occurring in the thin film transistor 600 may be reduced by light emitted from the LED 400.

In addition, since the metal reflective film 200 is included on the substrate 100 in the LED-TFT integration structure 10 and the LED-TFT integration structure 10 extracts light generated from the light emitting layer 420 of the LED 400 using the metal reflective film 200 upward, the amount of light emitted from the top of the LED 400 and light extraction efficiency may be increased.

Hereinafter, specific features of the LED-TFT integration structure 10 of the present invention are described with reference to FIGS. 3 to 9.

FIG. 3 illustrates the substrate 100, metal reflective film 200, and buffer layer 300 formed according to the fabrication method of FIG. 2.

Referring to FIGS. 1, 2 and 3, LED-TFT integration structures 10 according to embodiments of the present invention may be fabricated through a step (S110) of forming the metal reflective film 200 on the substrate 100 and a step (S120) of forming the buffer layer 300 on the metal reflective film 200.

For example, the metal reflective film 200 may be composed of at least one of Ag and Al.

Light generated from light generated from the LED 400 may be reflected by the metal reflective film 200, thereby increasing the light extraction efficiency of the LED 400.

For example, the metal reflective film 200 may reflect light generated from the light emitting layer 420 of the LED 400 and extract it upward.

Accordingly, the LED-TFT integration structure 10 may reflect light generated from the LED 400 using the metal reflective film 200, thereby increasing the amount of light emitted from the top of the LED 400 and light extraction efficiency.

The LED-TFT integration structure 10 may include the buffer layer 300 disposed between the LED 400 and the metal reflective film 200.

The buffer layer 300 may be a layer to facilitate the deposition of a semiconductor thin film of the LED 400.

For example, the buffer layer 300 may help the semiconductor layer of the LED 400 have a single crystal plane.

In an embodiment, the buffer layer 300 may be composed of at least one of aluminum nitride and zinc oxide.

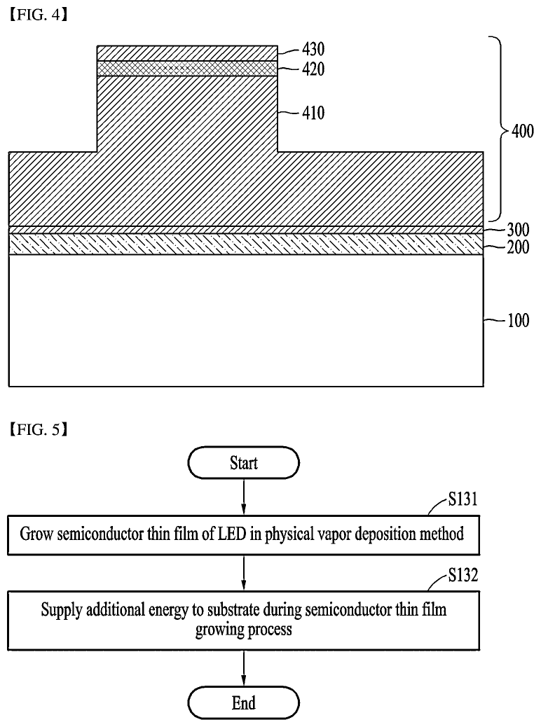

FIG. 4 illustrates an LED 400 formed according to the fabrication method of FIG. 2, and FIG. 5 is a flowchart illustrating an embodiment of a method of forming the LED 400 of FIG. 4.

Referring to FIGS. 1 to 5, LED-TFT integration structures 10 according to embodiments of the present invention may be fabricated through the step (S130) of forming the LED 400 in a light emitting area on the substrate 100.

The LED 400 may include a first semiconductor layer 410, a light emitting layer 420, and a second semiconductor layer 430. The first semiconductor layer 410 may be an n-type semiconductor layer. The light emitting layer 420 may be an active layer. The second semiconductor layer 430 may be a p-type semiconductor layer.

For example, the light emitting layer 420 may generate light when electrons supplied from the first semiconductor layer 410 and holes supplied from the second semiconductor layer 430 are combined with each other.

As representative conventional technologies for depositing the semiconductor layer of the LED 400, there are the Metal Organic CVD (MOCVD) method, the Molecular Beam Epitaxy (MBE) method, are the like. When the semiconductor layer is deposited by these methods, the substrate 100 should be maintained in a heated state at about 1,000° C. to 1,100° C.

Accordingly, when using the Metal Organic CVD (MOCVD) method or the Molecular Beam Epitaxy (MBE) method, a material for the substrate 100 on which a semiconductor thin film is to be formed is limited to single crystal sapphire (Al₂O₃), silicon (Si), silicon carbide (SiC), etc. having relatively high deformation temperature.

However, this substrate 100 is difficult to apply to the production of large-area wafers of 12 inches or more, and the production cost is high, making it difficult to implement large-area displays such as large TVs.

In addition, when growing a semiconductor thin film on the substrate 100 made of sapphire, a transfer process of transferring the LED 400 on a glass substrate 100 is essential in the micro LED manufacturing process, so that there is a problem that the production cost of micro LEDs increases significantly due to the transfer process.

To address this problem, a semiconductor thin film of the LED 400 of the present invention may be grown at low temperature by supplying additional energy to the physical vapor deposition method and the chemical vapor deposition method.

For example, as shown in FIG. 5, the step of forming the LED 400 may include a step (S131) of growing a semiconductor thin film of the LED 400 in the physical vapor deposition method; and a step (S132) of supplying additional energy to the substrate 100 during the semiconductor thin film growing process.

Specifically, the physical vapor deposition method used in the thin film growing process may be at least one of a sputtering method, an e-beam deposition method and a thermal evaporation method.

In the thin film growing process, additional energy supplied to the substrate 100 may be at least one of ion beam, electron beam, plasma, ultraviolet ray, laser and LED light.

For example, in the LED-TFT integration structure 10 of the present invention, a sputtering ion beam is supplied during the thin film growth process, so that a portion of the energy required for the semiconductor layer deposition is provided as the kinetic energy of ion beam. Accordingly, the growth temperature of the semiconductor thin film may be lowered compared to a conventional process.

In an embodiment, at least one of helium (He), neon (Ne), argon (Ar), krypton (Kr), xenon (Xe), radon (Rn), hydrogen (H₂), oxygen (O₂), nitrogen (N₂), chlorine (Cl₂) and ammonia (NH₃) may be used for the ion beam sputtering.

In an embodiment, a sputtering target used in the ion beam sputtering may include gallium (Ga) or gallium nitride (GaN).

When the thin film deposition process of the semiconductor layer is performed at a relatively low temperature, the range of the substrate 100 that can be used in the manufacturing process may be expanded.

For example, the substrate 100 may be an amorphous substrate or a polycrystalline substrate.

For example, the substrate 100 may be at least one of a glass substrate, a stainless steel substrate, and a polymer substrate which have a deformation temperature of 650° C. or lower.

When the fabrication process of the semiconductor layer of the LED 400 is performed at a relatively low temperature and, accordingly, the range of the substrate 100 available in the fabrication process is expanded, the metal reflective film 200 may be formed on the substrate 100.

For example, in the LED-TFT integration structure 10, a silver (Ag) reflective film or an aluminum (Al) reflective film may be formed on the glass substrate 100.

When a semiconductor thin film with a single crystal plane is grown from a thin film growth stage using ion beam sputtering, the production process of the LED-TFT integration structure 10 may be simplified, and the manufacturing cost of the LED-TFT integration structure 10 may be reduced.

In addition, when using ion beam sputtering, a nitride semiconductor layer may be deposited on a glass substrate 100 with a deformation temperature of 650° C. or less. When the nitride semiconductor layer is directly deposited on the glass substrate 100, the LED 400 may be fabricated directly on a backplane unlike the case where a nitride semiconductor layer is deposited on the sapphire substrate 100.

When a semiconductor layer is deposited using ion beam sputtering as described above, an LED chip fabrication process and a LED transfer process may be omitted in the micro-LED display production process.

Accordingly, the production cost due to the LED chip fabrication and transfer processes may be reduced by applying the present invention, so the manufacturing cost of large displays including micro LEDs such as large-area 4K Micro—the LED TV may be dramatically reduced.

FIG. 6 illustrates a protective layer 500 formed according to the fabrication method of FIG. 2.

Referring to FIGS. 1, 2 and 6, LED-TFT integration structures 10 according to embodiments of the present invention may be fabricated through a step (S140) of forming the protective layer 500 on the LED 400.

In the LED-TFT integration structure 10, the protective layer 500 may serve as an insulating layer. In addition, the protective layer 500 may serve as a planarization layer.

The protective layer 500 may be composed of an organic material such as Photo Acryl Compound (PAC) In addition, the protective layer 500 may be composed of an inorganic material such as SiO₂ or SiNx.

The protective layer 500 may be formed as a single layer. In addition, the protective layer 500 may be formed of multiple layers.

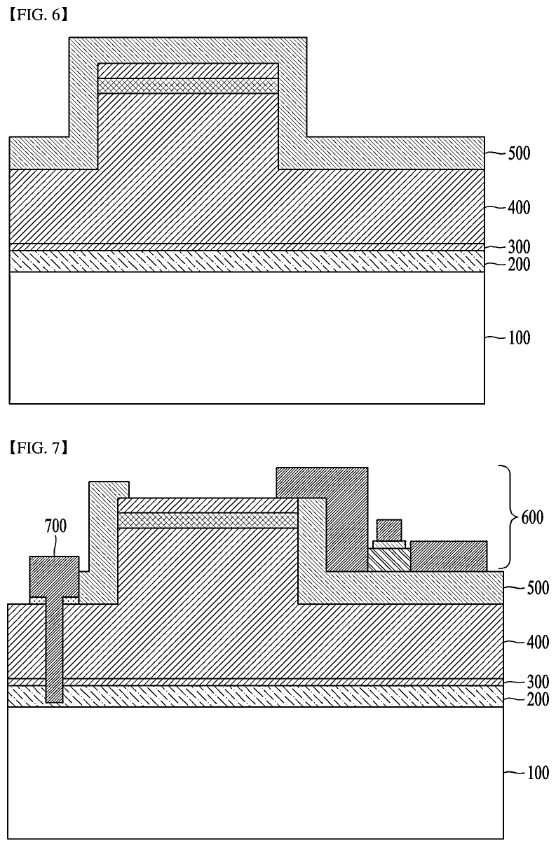

FIG. 7 illustrates a thin film transistor 600 formed according to the fabrication method of FIG. 2.

Referring to FIGS. 1, 2 and 7, the LED-TFT integration structure 10 may be fabricated through the step (S150) of forming the thin film transistor 600 in a driving area of the substrate 100.

The thin film transistor 600 may include an active layer 610, a gate 620, a source thin film 630, and a drain thin film 640.

The active layer 610 of the thin film transistor 600 may be an oxide semiconductor including at least one of amorphous silicon, nanocrystalline silicon, microcrystalline silicon, polycrystalline silicon, and InGaZnO-based materials.

In an embodiment, the active layer 610 of the thin film transistor 600 may be disposed lower than the light emitting layer 420 of the LED 400.

For example, since the active layer 610 of the thin film transistor 600 in the LED-TFT integration structure 10 of the present invention is disposed lower than the light emitting layer 420 of the LED 400, light emitted from the LED 400 may be prevented from flowing into the thin film transistor 600.

In addition, the source thin film 630 of the thin film transistor 600 may block light emitted from the LED 400 from flowing into the active layer 610 of the thin film transistor 600.

For example, since the source thin film 630 of the thin film transistor 600 in the LED-TFT integration structure 10 of the present invention is formed high, light generated from the LED 400 may be blocked from flowing into the active layer 610 of the thin film transistor 600.

Since the active layer 610 of the thin film transistor 600 in the LED-TFT integration structure 10 is disposed lower than the light emitting layer 420 of the LED 400 as described above, leakage current occurring in the thin film transistor 600 due to light emitted from the LED 400 may be reduced.

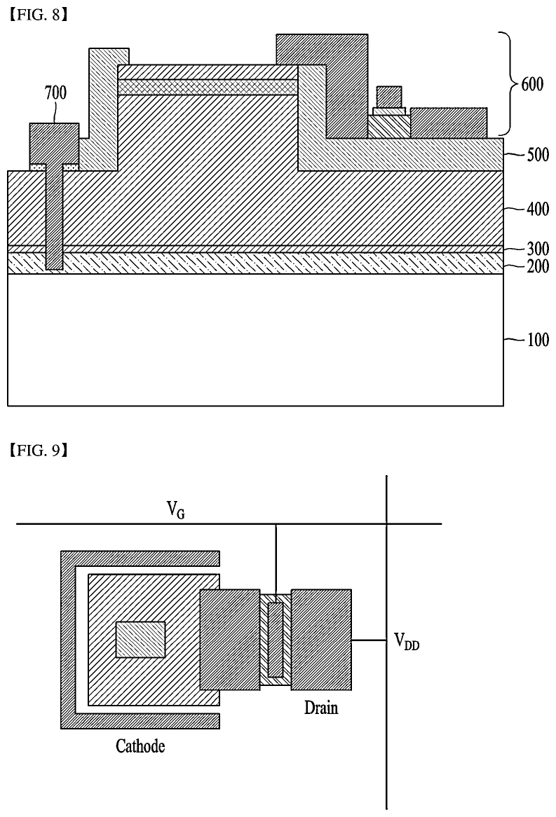

FIG. 8 illustrates electrical connection between the cathode of the LED 400 and the metal reflective film 200 according to the fabrication method of FIG. 2.

Referring to FIGS. 1, 2 and 8, the LED-TFT integration structure 10 may be fabricated through the step (S160) of electrically connecting a cathode of the LED 400 to the metal reflective film 200 using the ohmic contact metal 700.

As shown in FIG. 8, the ohmic contact metal 700 may electrically connect the cathode and the metal reflective film 200 to each other.

For example, the cathode of the LED 400 may be connected to the first semiconductor layer 410 through the N—GaN the ohmic contact metal 700. The cathode of the LED 400 may be connected to the metal reflective film 200 through a contact hole (VIA).

For example, the cathode may be composed of at least one of Ag and Al as in the metal reflective film 200, and may be composed of metals different from the metal reflective film 200. For example, as the cathode of the LED 400 is electrically connected to the metal reflective film 200 through the ohmic contact metal 700, the metal reflective film 200 may be used as a common negative electrode.

Accordingly, when the LED-TFT integration structure 10 uses the metal reflective film 200 as a common negative electrode, the electrical characteristics of the LED 400 may be improved, the fabrication process of the LED-TFT integration structure 10 may be simplified, and the manufacturing cost of the LED-TFT integration structure 10 may be reduced.

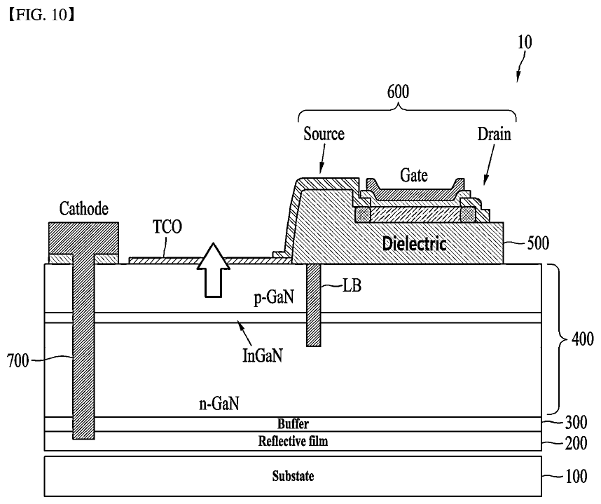

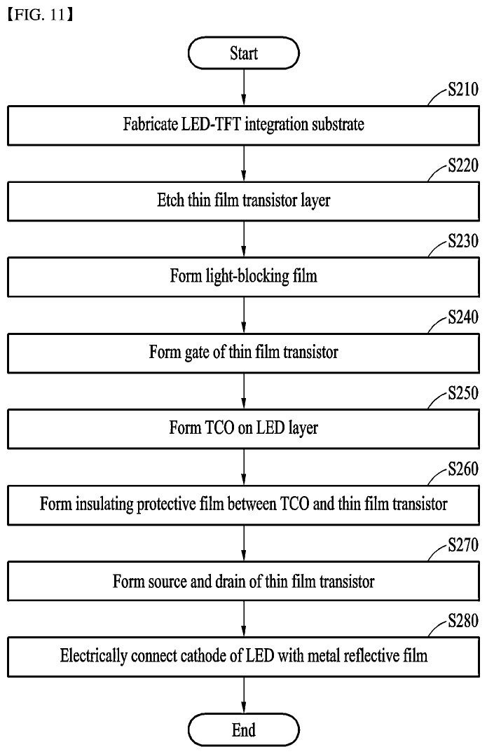

FIG. 9 illustrates a gate line and data line connected to the thin film transistor 600.

As shown in FIG. 9, the source thin film 630 of the thin film transistor 600 may be connected to a data line. The gate 620 of the thin film transistor 600 may be connected to a gate line.

For example, the LED-TFT integration structure 10 is connected to the data line and the gate line and receives data voltage and gate voltage, thereby outputting target light.

FIG. 10 is a sectional view illustrating a Light-Emitting Device-Thin Film Transistor (LED-TFT) integration structure 10 according to another embodiment of the present invention, and FIG. 11 is a flowchart illustrating a method of fabricating the LED-TFT integration structure 10 of FIG. 10.

Referring to FIG. 10, the LED-TFT integration structure 10 of the present invention may include a substrate 100, a metal reflective film 200, a buffer layer 300, an LED 400, a protective layer 500, a thin film transistor 600, and an ohmic contact metal 700.

Specifically, the LED-TFT integration structure 10 may include a substrate 100 including a light emitting area and a driving area; a metal reflective film 200 formed on the substrate 100; a buffer layer 300 formed on the metal reflective film 200; an LED 400 disposed on the light emitting area; a protective layer 500 formed on the LED 400; a thin film transistor 600 disposed on the driving area and configured to drive the LED 400; and an ohmic contact metal 700 configured to electrically connect a cathode of the LED 400 to the metal reflective film 200.

For example, the LED 400 and the thin film transistor 600 may be integrally formed on the substrate 100.

In an embodiment, the LED 400 and the thin film transistor 600 may be fabricated in batches using an LED-TFT integration substrate.

For example, the LED-TFT integration substrate may be formed by sequentially laminating a substrate 100, a metal reflective film 200, a buffer layer 300, an LED layer, a protective layer 500, and a thin film transistor layer.

Referring to FIG. 11, the LED-TFT integration structure 10 may be fabricated through a step (S210) of fabricating an LED-TFT integration substrate; a step (S220) of etching the thin film transistor layer; a step (S230) of forming a light-blocking film LB; a step (S240) of forming a gate 620 of the thin film transistor 600; a step (S250) of forming TCO on the LED layer; a step (S260) of forming an insulating protective film DP between the TCO and the thin film transistor 600; a step (S270) of forming a source thin film 630 and drain thin film 640 of the thin film transistor 600; and a step (S280) of electrically connecting a cathode of the LED 400 to the metal reflective film 200 using an ohmic contact metal 700.

The LED-TFT integration structure 10 of the present invention may be directly manufactured on the substrate 100 without a transfer process.

In addition, the LED-TFT integration structure 10 may be fabricated in batches on the substrate 100 by using LED-TFT integration substrate.

In addition, since the metal reflective film 200 is included on the substrate 100 in the LED-TFT integration structure 10 and the LED-TFT integration structure 10 extracts light generated from the light emitting layer 420 of the LED 400 using the metal reflective film 200 upward, the amount of light emitted from the top of the LED 400 and light extraction efficiency may be increased.

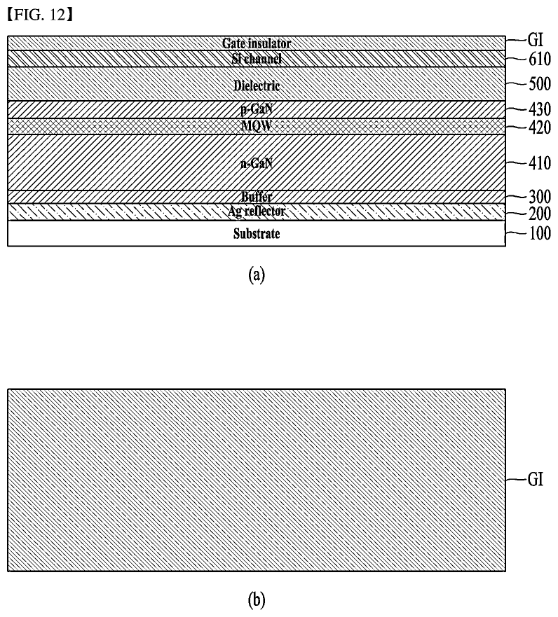

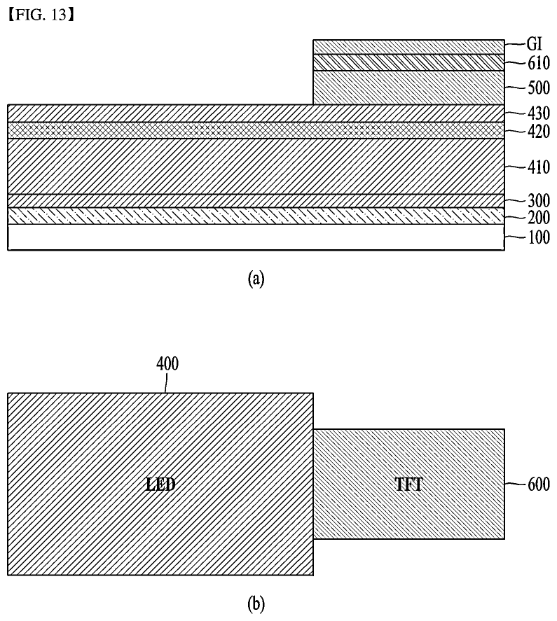

Hereinafter, specific features of the LED-TFT integration structure 10 of the present invention are described with reference to FIGS. 12 to 19.

FIG. 12 illustrates an LED-TFT integration substrate manufactured according to the fabrication method of FIG. 11.

Referring to FIGS. 10, 11, and 12, the LED-TFT integration structure 10 may be fabricated through the step (S210) of fabricating an LED-TFT integration substrate.

On the LED-TFT integration substrate, the substrate 100, the metal reflective film 200, the buffer layer 300, an LED layer, the protective layer 500, and a thin film transistor layer may be sequentially laminated.

Here, the LED layer may be the LED 400 by the process according to the fabrication method of FIG. 11. In addition, the thin film transistor layer may be the thin film transistor 600 by the process according to the fabrication method of FIG. 11.

The LED-TFT integration substrate may be fabricated in advance before the fabrication process of the LED-TFT integration structure 10.

For example, the LED-TFT integration structure 10 is fabricated according to the fabrication method of FIG. 11 based on the prefabricated LED-TFT integration substrate, so it may be fabricated in batches on the substrate 100 regardless of the thin film transistor 600 fabrication process and the LED 400 fabrication process.

FIG. 13 illustrates a thin film transistor layer etched according to the fabrication method of FIG. 11.

Referring to FIGS. 10, 11, and 13, the LED-TFT integration structure 10 may be fabricated through the step (S220) of etching the thin film transistor layer.

The thin film transistor layer may include an active layer 610 of the thin film transistor 600 and a gate insulator GI.

The thin film transistor layer may be etched to expose the LED layer.

For example, a portion of the thin film transistor layer excluding a driving area may be etched to form the thin film transistor 600 on the driving area.

Here, the portion of the protective layer 500 may be etched together with the thin film transistor layer.

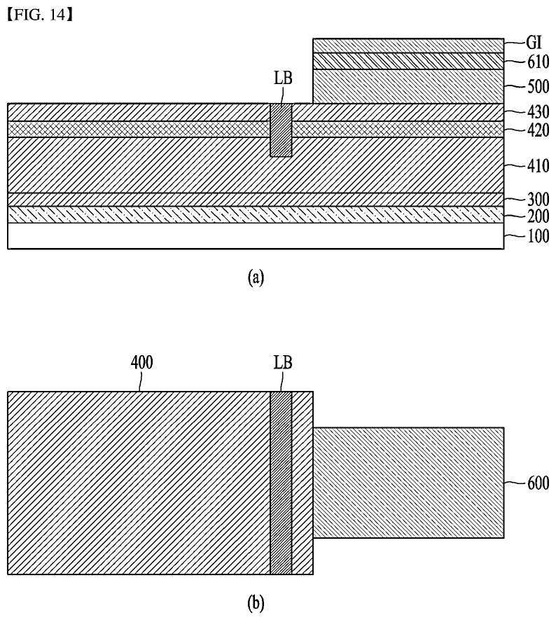

FIG. 14 illustrates a light-blocking film LB formed according to the fabrication method of FIG. 11.

Referring to FIGS. 10, 11, and 14, the LED-TFT integration structure 10 may be fabricated through the step (S230) of forming the light-blocking film LB.

The light-blocking film LB may prevent light emitted from the LED 400 from flowing into the thin film transistor 600.

For example, the light-blocking film LB is formed to vertically cross the light emitting layer 420 of the LED layer, thereby blocking light generated from the LED 400 from flowing into the active layer 610 of the thin film transistor 600.

For example, a thin insulating film may be added to the edge of the light-blocking film LB.

Since the LED-TFT integration structure 10 includes the light-blocking film LB as described above, leakage current occurring in the thin film transistor 600 due to light emitted from the LED 400 may be reduced.

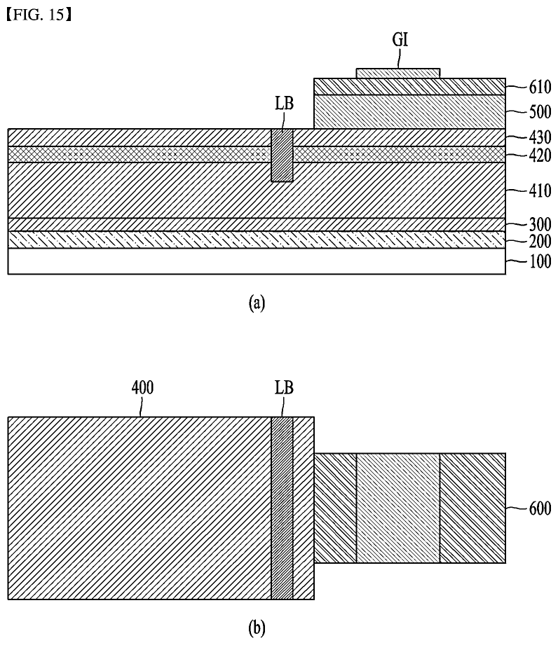

FIG. 15 illustrates a gate 620 of the thin film transistor 600 formed according to the fabrication method of FIG. 11.

Referring to FIGS. 10, 11, and 15, the LED-TFT integration structure 10 may be fabricated through the step (S240) of forming a gate 620 of the thin film transistor 600.

For example, the gate 620 may be formed by patterning the gate insulator GI of the thin film transistor layer.

The gate 620 may be connected to a gate line and receive gate voltage.

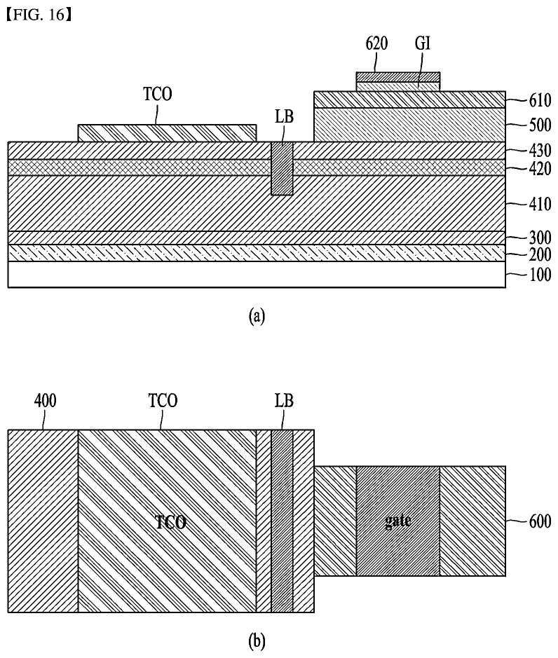

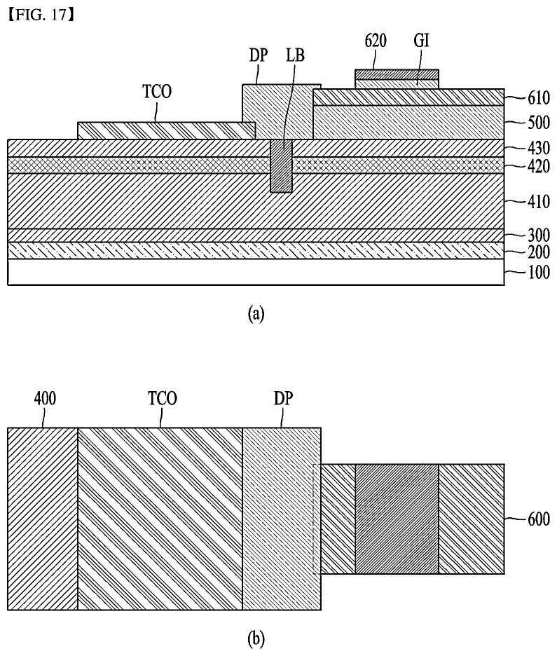

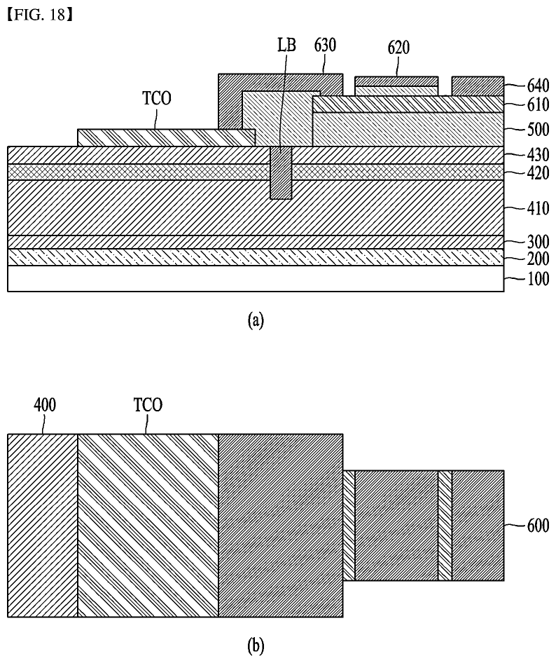

FIG. 16 illustrates TCO formed on the LED layer according to the fabrication method of FIG. 11.

Referring to FIGS. 10, 11, and 16, the LED-TFT integration structure 10 may be fabricated through a step (S250) of forming TCO on the LED layer.

For example, TCO may be formed in a light emitting area on the LED layer.

TCO may include a transparent conductive material to allow light output from the light emitting layer 420 of the LED 400 to pass upward.

In an embodiment, TCO may perform a p-ohmic contact function.

The LED 400 may include a first semiconductor layer 410, a light emitting layer 420, and a second semiconductor layer 430.

Specifically, TCO may be made of a transparent material such that the light emitting layer 420 of the LED 400 can be output to the outside.

For example, TCO may include at least one of Indium Tin Oxide (ITO), Indium Zinc Oxide (IZO), Indium Zinc Tin Oxide (IZTO), Indium Cesium Oxide (ICO), Indium Tungsten Oxide (IWO), aluminum-added Zinc Oxide (ZnO), PEDOT:PSS, polyaniline, and polythiophen.

The TCO may be electrically connected to the LED 400. For example, the TCO may be electrically connected to the second semiconductor layer 430 of the LED 400 through an ohmic electrode.

FIG. 17 illustrates an insulating protective film DP formed between the TCO and the thin film transistor 600 according to the fabrication method of FIG. 11.

Referring to FIGS. 10, 11, and 17, the LED-TFT integration structure 10 may be fabricated through a step (S260) of forming an insulating protective film DP between the TCO and the thin film transistor 600.

The insulating protective film DP is formed between the TCO and the thin film transistor 600, thereby preventing light emitted from the TCO from flowing into the thin film transistor 600.

For example, the insulating protective film DP may include at least one of SiO₂, TiO₂, ZrO₂, and Al₂O₃.

FIG. 18 illustrates a source thin film 630 and drain thin film 640 of the thin film transistor 600 formed according to the fabrication method of FIG. 11.

Referring to FIGS. 10, 11, and 18, the LED-TFT integration structure 10 may be formed through the step (S270) of forming a source thin film 630 and drain thin film 640 of the thin film transistor 600.

The thin film transistor 600 may include the active layer 610, the gate 620, the source thin film 630, and the drain thin film 640.

For example, the source thin film 630 may be formed on the insulating protective film DP.

The source thin film 630 may electrically connect TCO, which performs a p-ohmic contact function, to the active layer 610.

For example, the drain thin film 640 may be formed on the active layer 610.

the active layer 610 of the thin film transistor 600 may be an oxide semiconductor including at least one of amorphous silicon, nanocrystalline silicon, microcrystalline silicon, polycrystalline silicon, and InGaZnO-based materials.

For example, the source thin film 630 of the thin film transistor 600 may be connected to a data line and receive data voltage.

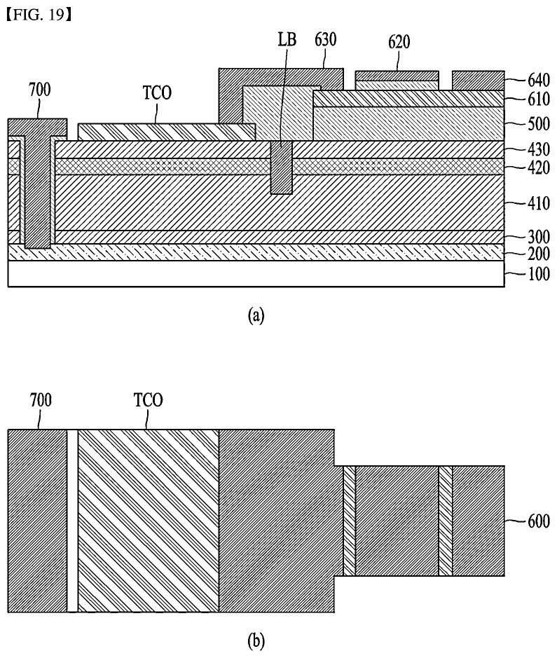

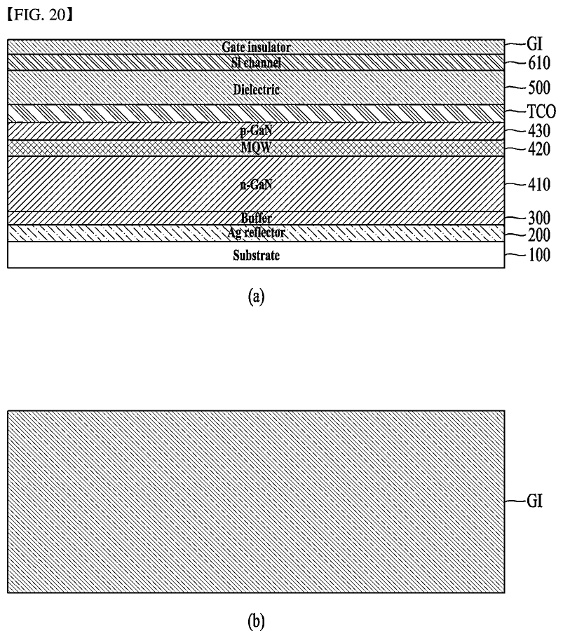

FIG. 19 illustrates electrically connecting the cathode of the LED 400 to the metal reflective film 200 according to the fabrication method of FIG. 11.

Referring to FIGS. 10, 11, and 19, the LED-TFT integration structure 10 may be fabricated through the step (S280) of electrically connecting a cathode of the LED 400 to the metal reflective film 200 using the ohmic contact metal 700.

As shown in FIG. 19, the ohmic contact metal 700 may electrically connect the cathode and the metal reflective film 200 to each other.

For example, the cathode of the LED 400 may be connected to the first semiconductor layer 410 through the N—GaN the ohmic contact metal 700. The cathode of the LED 400 may be connected to the metal reflective film 200 through a contact hole (VIA).

For example, the cathode may be composed of at least one of Ag and Al as in the metal reflective film 200, and may be composed of metals different from the metal reflective film 200.

For example, as the cathode of the LED 400 is electrically connected to the metal reflective film 200 through the ohmic contact metal 700, the metal reflective film 200 may be used as a common negative electrode.

That is, when the LED-TFT integration structure 10 uses the metal reflective film 200 as a common negative electrode, the electrical characteristics of the LED 400 may be improved.

When the LED-TFT integration structure 10 of the present invention includes the LED-TFT integration substrate as described above, it may be formed in batches on the substrate 100.

Accordingly, the fabrication process of the LED-TFT integration structure 10 may be simplified, and the manufacturing cost of the LED-TFT integration structure 10 may be reduced.

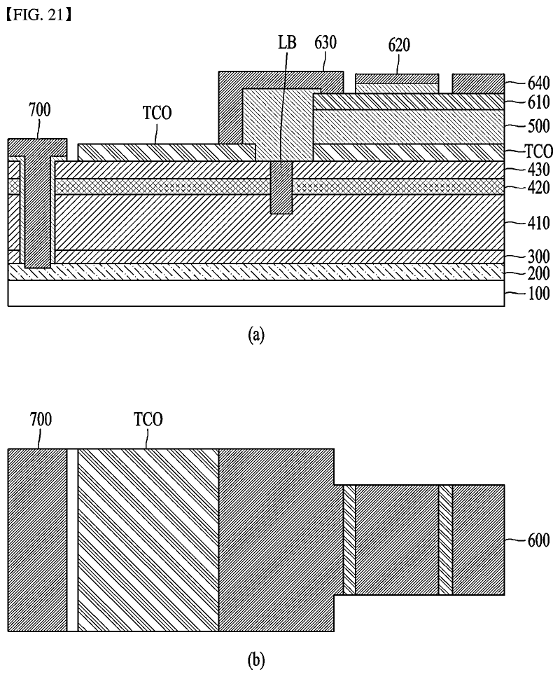

FIG. 20 illustrates another embodiment of an LED-TFT integration substrate, and FIG. 21 illustrates an LED-TFT integration structure 10 fabricated using the LED-TFT integration substrate of FIG. 20.

Referring to FIG. 20, the LED 400 and the thin film transistor 600 may be fabricated in batches by using the LED-TFT integration substrate.

For example, the LED-TFT integration substrate may be formed by sequentially laminating the substrate 100, the metal reflective film 200, the buffer layer 300, an LED layer, TCO, the protective layer 500, and a thin film transistor layer.

That is, the LED-TFT integration substrate may further include TCO.

In this case, since the fabrication process of the LED-TFT integration structure 10 does not require a step of forming TCO on the LED layer, the fabrication process of the LED-TFT integration structure 10 may be minimized.

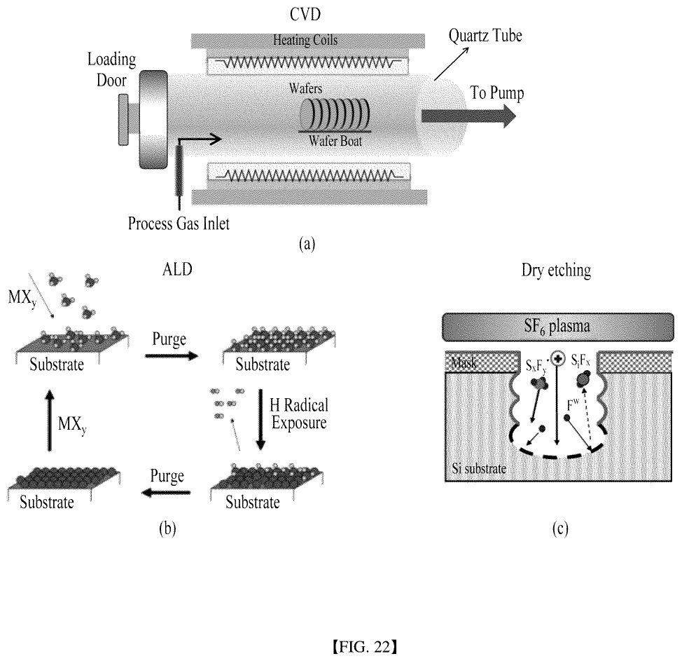

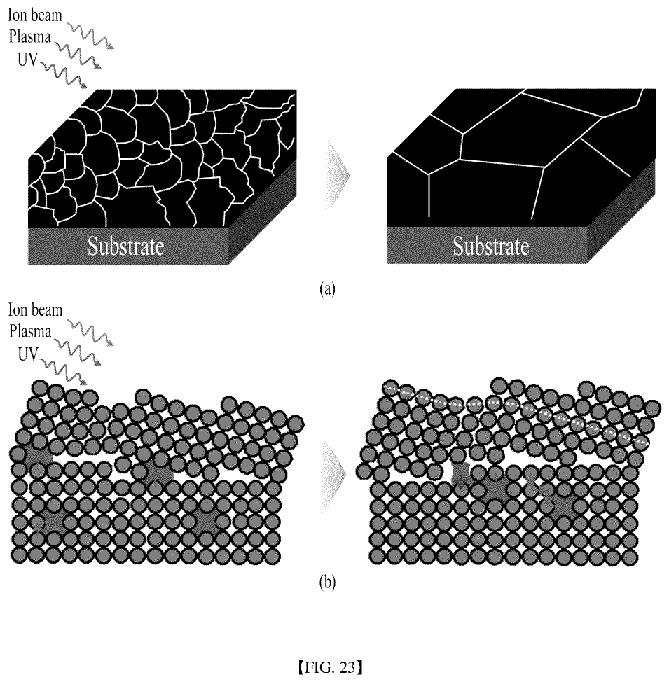

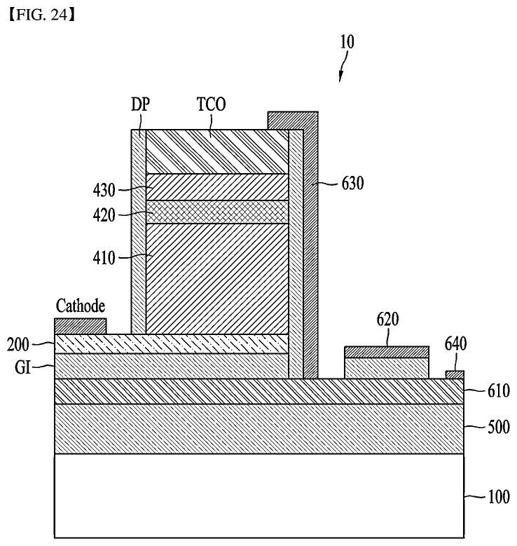

FIG. 22 illustrates a physical vapor deposition method to form a semiconductor thin film of the LED 400, and FIG. 23 illustrates the types of additional energy to form the semiconductor thin film of the LED 400.

In an embodiment, the semiconductor thin film of the LED 400 may be grown at low temperature by supplying additional energy to the physical vapor deposition method and the chemical vapor deposition method.

Accordingly, the substrate 100 may be at least one of a glass substrate, a stainless steel substrate, and a polymer substrate.

Referring to FIG. 22, the physical vapor deposition method may use at least one of a sputtering method, an e-beam deposition method and a thermal evaporation method.

Referring to FIG. 23, the additional energy may use at least one of ion beam, electron beam, plasma, ultraviolet ray, laser and LED light.

Accordingly, some of the energy required for deposition of the semiconductor thin film of the LED 400 may be provided as additional energy (e.g., ion beam energy, plasma energy, and UV energy) rather than thermal energy.

That is, when the semiconductor thin film of the LED 400 is supplied with at least one additional energy of ion beam, electron beam, plasma, ultraviolet ray, laser, and LED light source, the mobility of atoms and molecules reaching the semiconductor thin film may be improved.

For example, the LED-TFT integration structure 10 may use an ion beam sputtering method in which a sputtering ion beam is provided during a thin film growth process.

When using ion beam sputtering, a portion of energy required for deposition of a semiconductor layer is provided by the kinetic energy of ion beam, so the growth temperature of a semiconductor thin film may be lowered.

At least one of helium (He), neon (Ne), argon (Ar), krypton (Kr), xenon (Xe), radon (Rn), hydrogen (H₂), oxygen (O₂), nitrogen (N₂), chlorine (Cl₂) and ammonia (NH₃) may be used for the ion beam sputtering.

A sputtering target used in the ion beam sputtering may include gallium (Ga) or gallium nitride (GaN).

When the semiconductor thin film of the LED 400 is deposited at a relatively low temperature, the range of the substrate 100 that can be used in the manufacturing process may be expanded.

For example, the substrate 100 may be an amorphous substrate or a polycrystalline substrate.

For example, the substrate 100 may be at least one of a glass substrate, a stainless steel substrate, and a polymer substrate which have a deformation temperature of 650° C. or lower.

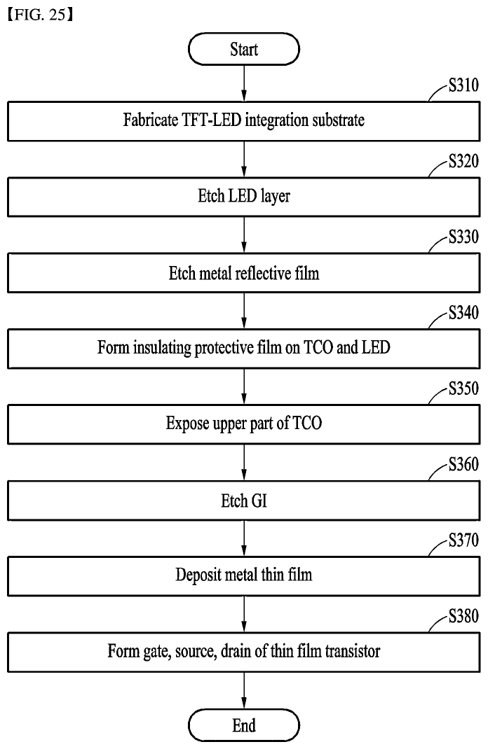

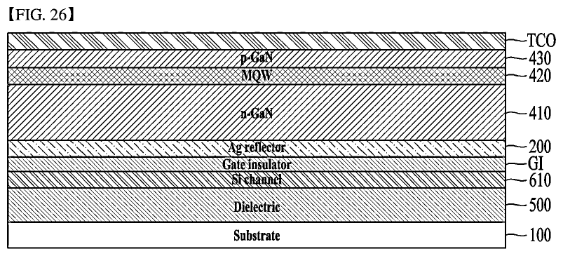

FIG. 24 illustrates a sectional view of an LED-TFT integration structure 10 according to another embodiment of the present invention, and FIG. 25 is a flowchart illustrating a method of fabricating the LED-TFT integration structure 10 of FIG. 24.

Referring to FIG. 24, the LED-TFT integration structure 10 may include a substrate 100 including a light emitting area and a driving area; a protective layer 500 formed on the substrate 100; a thin film transistor 600 disposed in the driving area and configured to drive an LED 400; a metal reflective film 200 formed on the thin film transistor 600; an LED 400 disposed in the light emitting area; and TCO formed on the LED 400.

For example, the thin film transistor 600 and the LED 400 may be integrally formed on the substrate 100.

In an embodiment, the LED 400 and the thin film transistor 600 may be fabricated in batches by using a TFT-LED integration substrate.

In particular, in the LED-TFT integration structure 10, the LED 400 may be formed on the thin film transistor 600.

Referring to FIG. 25, the LED-TFT integration structure 10 may be fabricated through a step (S310) of fabricating a TFT (600)-LED (400) integration structure, a step (S320) of etching the LED layer, a step (S330) of etching the metal reflective film 200, a step (S340) of forming an insulating protective film DP on the TCO and the LED 400, a step (S350) of exposing an upper part of the TCO, a step (S360) of etching a gate insulator GI, a step (S370) of depositing a metal thin film, and a step (S380) of forming a gate 620, source thin film 630, and drain thin film 640 of the thin film transistor 600.

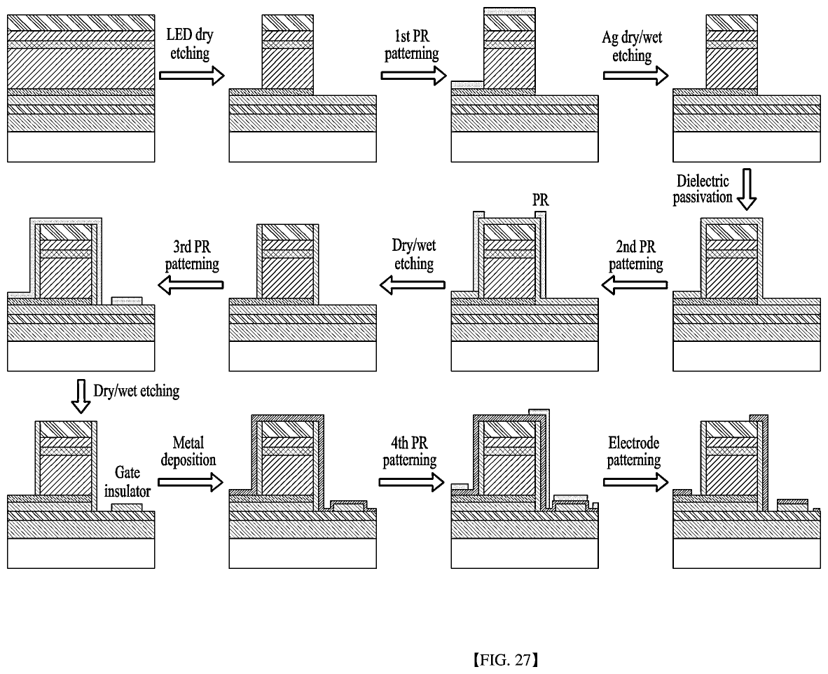

FIG. 26 illustrates a TFT-LED integration substrate manufactured according to the fabrication method of FIG. 25.

Referring to FIG. 26, the TFT-LED integration substrate may be formed, for example, by sequentially laminating the substrate 100, the protective layer 500, a thin film transistor layer, the metal reflective film 200, an LED layer, and the TCO.

That is, in the TFT-LED integration substrate, the LED layer may be formed on the thin film transistor layer, unlike the LED-TFT integration substrate.

Accordingly, in the LED-TFT integration structure 10, the LED 400 may be formed on the thin film transistor 600.

FIG. 27 illustrates a process of fabricating the TFT-LED integration structure 10 using the LED-TFT integration substrate of FIG. 26.

By the step (S310) of fabricating the TFT-LED integration substrate, the TFT-LED integration substrate in which the substrate 100, the protective layer 500, a thin film transistor layer, the metal reflective film 200, an LED layer, and the TCO are sequentially laminated may be fabricated.

In the step (S320) of etching the LED layer, a portion excluding a light emitting area of the LED layer may be etched to expose the thin film transistor layer.

Here, the TCO on the LED layer may be etched together with the LED layer.

In the step (S330) of etching the metal reflective film 200, first PR patterning may be performed, and the metal reflective film 200 may be dry etched or wet etched.

For example, as the metal reflective film 200 is etched, a driving area of the thin film transistor layer may be exposed.

In the step (S340) of forming an insulating protective film DP on the TCO and the LED 400, the insulating protective film DP may be deposited to protect the LED 400.

For example, the insulating protective film DP may include at least one of SiO₂, TiO₂, ZrO₂, and Al₂O₃.

In the step (S350) of exposing the upper part of the TCO, second PR patterning may be performed, and the upper part of the TCO may be exposed through dry etching or wet etching. The TCO may be made of a transparent material so that a light source emitted from the light emitting layer 420 of the LED 400 can be output to the outside.

Accordingly, the light output from the light emitting layer 420 of the LED 400 may pass through the exposed upper part of the TCO.

In the step (S360) of etching the gate insulator, third PR patterning may be performed, and the gate insulator GI may be dry etched or wet etched.

In the step (S370) of depositing a metal thin film, a metal thin film for electrically connecting the LED 400 and the thin film transistor 600 to each other may be formed by depositing a metal material.

In the step (S380) of forming a gate 620, source thin film 630, and drain thin film 640 of the thin film transistor 600, fourth PR patterning and electrode patterning may be performed, thereby forming a gate 620, a source thin film 630, and a drain thin film 640.

As described above, the LED-TFT integration structures 10 according to embodiments of the present invention may be directly manufactured on the substrate 100 without a transfer process.

In addition, the LED-TFT integration structure 10 may be fabricated in batches on the substrate 100 by using the TFT-LED integration substrate.

In addition, the LED-TFT integration structure 10 may include the metal reflective film 200 formed on the substrate 100 and extracts light, generated from the light emitting layer 420 of the LED 400, upward using the metal reflective film 200, thereby increasing the amount of light emitted from the top of the LED 400 and light extraction efficiency.

The apparatus described above may be implemented as a hardware component, a software component, and/or a combination of hardware components and software components. For example, the apparatus and components described in the embodiments may be achieved using one or more general purpose or special purpose computers, such as, for example, a processor, a controller, an arithmetic logic unit (ALU), a digital signal processor, a microcomputer, a field programmable gate array (FPGA), a programmable logic unit (PLU), a microprocessor, or any other device capable of executing and responding to instructions. The processing device may execute an operating system (OS) and one or more software applications executing on the operating system. In addition, the processing device may access, store, manipulate, process, and generate data in response to execution of the software. For ease of understanding, the processing apparatus may be described as being used singly, but those skilled in the art will recognize that the processing apparatus may include a plurality of processing elements and/or a plurality of types of processing elements. For example, the processing apparatus may include a plurality of processors or one processor and one controller. Other processing configurations, such as a parallel processor, are also possible.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. A Light-Emitting Device-Thin Film Transistor (LED-TFT) integration structure, comprising:
a substrate comprising a light emitting area and a driving area;
a metal reflective film formed on the substrate;
a buffer layer formed on the metal reflective film;
LED disposed in the light emitting area;
a protective layer formed on the LED;
a thin film transistor disposed in the driving area and configured to drive the LED; and
an ohmic contact metal for electrically connecting a cathode of the LED with the metal reflective film,
wherein the LED and the thin film transistor are integrally formed on the substrate.

2. The LED-TFT integration structure according to claim 1, wherein an active layer of the thin film transistor is disposed lower than a light emitting layer of the LED.

3. The LED-TFT integration structure according to claim 2, wherein a source thin film of the thin film transistor blocks light emitted from the LED from flowing into the active layer of the thin film transistor.

4. The LED-TFT integration structure according to claim 2, wherein the active layer of the thin film transistor is an oxide semiconductor comprising at least one of amorphous silicon, nanocrystalline silicon, microcrystalline silicon, polycrystalline silicon, and InGaZnO-based materials.

5. The LED-TFT integration structure according to claim 2, wherein the LED-TFT integration structure is fabricated by a process comprising:
forming a metal reflective film on a substrate;
forming a buffer layer on the metal reflective film;
forming an LED in a light emitting area on the substrate;
forming a protective layer on the LED;
forming a thin film transistor in a driving area on the substrate; and
electrically connecting a cathode of the LED with the metal reflective film using an ohmic contact metal.

6. The LED-TFT integration structure according to claim 1, wherein the LED and the thin film transistor are fabricated in batches using an LED-TFT integration substrate,
wherein, in the LED-TFT integration substrate, the substrate, the metal reflective film, the buffer layer, an LED layer, the protective layer, and a thin film transistor layer are sequentially laminated.

7. The LED-TFT integration structure according to claim 6, wherein the LED-TFT integration structure is fabricated by a process comprising:
fabricating an LED-TFT integration substrate;
etching the thin film transistor layer to expose the LED layer;
forming a light-blocking film;
forming a gate of the thin film transistor;
forming TCO on the LED layer;
forming an insulating protective film between the TCO and the thin film transistor;
forming a source thin film and drain thin film of the thin film transistor; and
electrically connecting a cathode of the LED with the metal reflective film using an ohmic contact metal.

8. The LED-TFT integration structure according to claim 1, wherein the LED and the thin film transistor are fabricated in batches using an LED-TFT integration substrate,
wherein, in the LED-TFT integration substrate, the substrate, the metal reflective film, the buffer layer, an LED layer, TCO, the protective layer, and a thin film transistor layer are sequentially laminated.

9. The LED-TFT integration structure according to claim 1, wherein the metal reflective film comprises at least one of Ag and Al, and reflects light generated from the LED to increase light extraction efficiency of the LED.

10. The LED-TFT integration structure according to claim 1, wherein a semiconductor thin film of the LED is grown at low temperature by supplying additional energy to a physical vapor deposition method and a chemical vapor deposition method, and
the substrate is at least one of a glass substrate, a stainless steel substrate, and a polymer substrate.

11. The LED-TFT integration structure according to claim 10, wherein the physical vapor deposition method uses at least one of a sputtering method, an e-beam deposition method and a thermal evaporation method.

12. The LED-TFT integration structure according to claim 10, wherein the additional energy comprises at least one of ion beam, electron beam, plasma, ultraviolet ray, laser and LED light.

13. An LED-TFT integration structure, comprising:
a substrate comprising a light emitting area and a driving area;
a protective layer formed on the substrate;
a thin film transistor disposed in the driving area and configured to drive the LED;
a metal reflective film formed on the thin film transistor;
an LED disposed in the light emitting area; and
TCO formed on the LED,
wherein the thin film transistor and the LED are integrally formed on the substrate.

14. The LED-TFT integration structure according to claim 13, wherein the LED and the thin film transistor are fabricated in batches using a TFT-LED integration substrate,
wherein, in the TFT-LED integration substrate, the substrate, the protective layer, a thin film transistor layer, the metal reflective film, an LED layer, and the TCO are sequentially laminated.

15. The LED-TFT integration structure according to claim 14, wherein the LED-TFT integration structure is fabricated by a process comprising:
fabricating the TFT-LED integration substrate;
etching the LED layer to expose the thin film transistor layer;
etching the metal reflective film;
forming an insulating protective film on the TCO and the LED;
exposing an upper part of the TCO;
etching GI;
depositing a metal thin film; and
forming a gate, source thin film, and drain thin film of the thin film transistor.
